(19) United States
(12) Patent Application Publication
(10) Pub. No.: US 2014/0292384 A1
(43) Pub. Date: Oct. 2, 2014

(54) METHODS OF MULTI-PROTOCOL SYSTEM AND INTEGRATED CIRCUIT FOR MULTI-PROTOCOL COMMUNICATION ON SINGLE WIRE

(71) Applicant: NEOENERGY MICROELECTRONICS, INC., Chupei City (TW)

(72) Inventors: Li-Te WU, Chupei City (TW); Ssu-Ying CHEN, Chupei City (TW); Stanley Rendau JAN, Chupei City (TW)

(73) Assignee: NEOENERGY MICROELECTRONICS, INC., Chupei City (TW)

(21) Appl. No.: 14/224,130

(22) Filed: Mar. 25, 2014

Related U.S. Application Data
(60) Provisional application No. 61/807,426, filed on Apr. 2, 2013.

(51) Int. Cl. H03K 3/011

(52) U.S. Cl. CPC H03K 3/011
USPC 327/143

(57) ABSTRACT

Methods of multi-protocol system and integrated circuit for multi-protocol communication on a single wire are provided. The method, adopted by a multi- protocol system containing a master device, a peripheral device and a slave device coupled together by a single wire, wherein the slave device is capable of operating in first and second operation modes. The method includes: receiving, by the slave device, an analog signal from the peripheral device on a single wire in the first operation mode; transmitting, by the master device, a digital signal containing a preamble pattern on the single wire; and after detecting the preamble pattern, switching, by the slave device, from the first to the second operation mode which includes suspending receiving the analog signal on the single wire, and communicating with the master device in serial digital data via the single wire.

### CROSS REFERENCE TO RELATED APPLICATIONS

This Application claims priority of U.S. Provisional Applications No. 61/807,426, filed on Apr. 2, 2013, the entirety of which is incorporated by reference herein.

### BACKGROUND OF THE INVENTION

1. Field of the Invention

The present invention relates to power systems, and in particular, to methods of multi-protocol system and integrated circuit for multi-protocol communication on a single wire.

2. Description of the Related Art

Switching mode power supply (SMPS) converters provide superior power conversion efficiency because an output voltage or output current is regulated with transistor switches that are either on or off so that the SMPS converters never operate in the linear region in which both current and voltage are nonzero. Therefore, since the transistor current and voltage is always close to zero, power dissipation is greatly reduced. Due to the high efficiencies, the SMPS converters have been found to be particularly useful in a variety of portable devices (e.g., mobile phones, digital cameras, tablets, digital music players, media players, portable disk drives, handheld game consoles, and other handheld consumer electronic devices). A feedback or flyback control is typically implemented into the SMPS converter to provide power regulation.

The SMPS converter typically employs a controller integrated circuit (hereinafter referred to as IC) having dedicated pin for detecting the environment parameters such as output power, voltage, or temperature for the feedback control. The internal configurations and parameters of the controller IC, which affect performance and behavior of the controller IC, are configured by the external hardware components such as resistors.

### BRIEF SUMMARY OF THE INVENTION

A detailed description is given in the following embodiments with reference to the accompanying drawings.

An embodiment of an integrated circuit is disclosed, wherein the integrated circuit is coupled to a digital circuitry and an analog circuitry, capable of operating in first and second operation modes, and comprises a single pin and a controller. In the first mode, the single pin is configured to receive an analog signal from the analog circuitry and receive a digital signal containing a preamble pattern from the digital circuitry. After detecting the preamble pattern, the controller, coupled to the single pin, is configured to switch from the first to the second operation mode to suspend receiving the analog signal via the single pin and communicating with the digital circuitry in serial digital data via the single pin.

An embodiment of a method is provided, adopted by an integrated circuit coupled to a digital circuitry and an analog circuitry, wherein the integrated circuit is capable of operating in first and second operation modes, the method comprising: receiving an analog signal from the analog circuitry on a single pin of the integrated circuit in the first operation mode; detecting a digital signal containing a preamble pattern on the single pin; and after detecting the preamble pattern, switching from the first to the second operation mode which comprises suspending receiving the analog signal on the single pin, and communicating with the digital circuitry in serial digital data via the single pin.

Another embodiment of a method is described, adopted by a multi-protocol system containing a digital circuitry, an analog circuitry and a slave device coupled together by a single wire, wherein the slave device is capable of operating in first and second operation modes, the method comprising: receiving, by the slave device, an analog signal from the analog circuitry on a single wire in the first operation mode; transmitting, by the digital circuitry, a digital signal containing a preamble pattern on the single wire; and after detecting the preamble pattern, switching, by the slave device, from the first to the second operation mode which comprises suspending receiving the analog signal on the single wire, and communicating with the digital circuitry in serial digital data via the single wire.

### BRIEF DESCRIPTION OF THE DRAWINGS

The present invention can be more fully understood by reading the subsequent detailed description and examples with references made to the accompanying drawings, wherein:

FIG. 1 is a block diagram of a multi-protocol communication system 1 operated on a single wire according to an embodiment of the invention;

FIG. 2 shows a multi-protocol write procedure according to an embodiment of the invention;

FIG. 3 shows a multi-protocol read procedure according to an embodiment of the invention;

FIG. 4 is a flowchart of a multi-protocol method 4 adopted by the slave device 10 according to an embodiment of the invention; and

FIG. 5 is a flowchart of a multi-protocol method 5 adopted by the multi- protocol communication system 1 according to an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

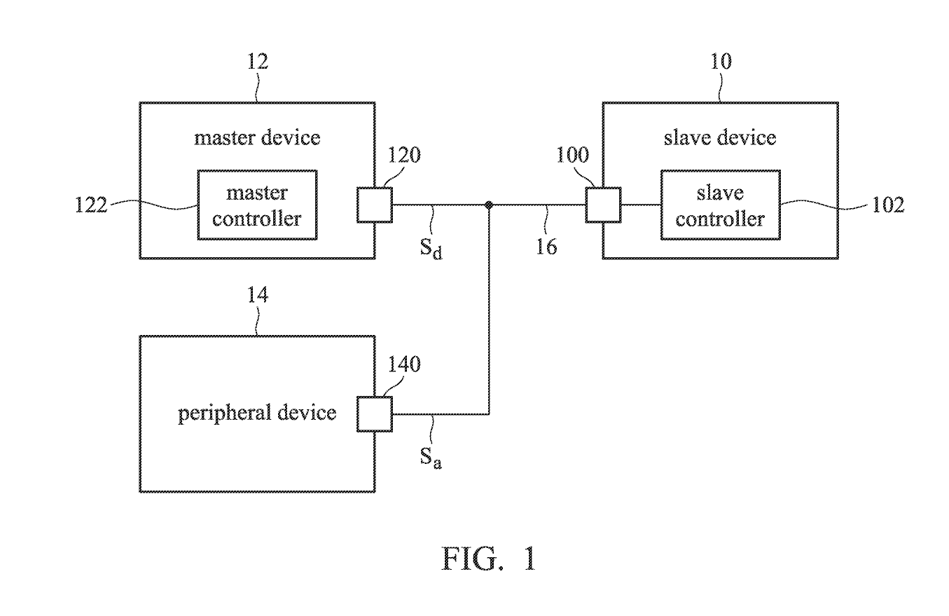

FIG. 1 is a block diagram of a multi-protocol communication system 1 operated by communication via a single wire according to an embodiment of the invention, including a master device 12, a slave device 10 and a peripheral device 14. The master device 12, the slave device 10 and the peripheral device 14 are connected together through a single wire 16.

The multi-protocol communication system 1 may be adopted in a factory testing environment, where internal parameters of the slave device 10 can be read and configured by the master device 12. The slave device 10 is a low pin count integrated circuit (IC), and may be a power converter controller, an isolation controller, or other low pin count ICs. The master device 12 may be a computer or a digital circuitry which can download measurements and parameters stored in registers or other nonvolatile memory (NVM) of the slave device 10 and program the parameters into the slave device 10 to meet a required or preferred performance such as the output power. The peripheral device 14 is an analog circuitry which contains electronic components such as resisters, capacitor, inductor and transistors, and serves to take measurements, feed back output powers, supply auxiliary power, or provide other analog functions. When the slave device 10 is a power converter IC, the peripheral device 14 may be a optic coupler, a capacitive isolator and an inductive isolator, isolating between a primary and a secondary sides of the power converter circuit

The slave device 10 is connected to the peripheral device 14 via the single wire 16 to receive an analog signal Sₐ which may indicate a voltage measurement, a current measurement, a temperature measurement, an output power detection, an auxiliary power supply, or other analog measurements taken by the peripheral device 14. Upon power-on or in a normal mode (first operation mode), the slave device 10 continuously obtains the analog signal Sₐ from the peripheral device 14, until the master device 12 initiates a command mode (second operation mode) by transmitting preamble data on the single wire 16. In the command mode, the slave device 10 suspends or creases receiving the analog signal Sₐ from the signal wire 16, instead, a digital signal S_{d} from the master device 12 is acquired to perform a requested operation on the slave device 10.

In one embodiment, the peripheral device 14 contains a resistor or a thermistor whose resistance varies considerably with temperature. The resistor or thermistor may be negative temperature coefficient (NTC) or positive temperature coefficient (PTC) correlated. An NTC resistor has the resistance which decreases as the temperature increases. A PTC resistor has the resistance which increases as the temperature increases. When the NTC resistor is adopted in the peripheral device 14, the slave device 10 can output a constant current through the single wire 16 to the peripheral device 14, and correspondingly detect a voltage on the single wire 16, which is established by the NTC resistor according to the ambient temperature. On the contrary, when the PTC resistor is adopted for the peripheral device 14, the slave device 10 will detect a voltage in proportion to the ambient temperature. Based on the detected voltage level of the analog signal Sₐ on the single wire 16, the slave device 10 can determine the ambient temperature of the multi-protocol communication system 1. In some embodiments, the slave device 10 is further configured with a temperature threshold, for example, 150° C. When the determined temperature exceeds 150° C., the slave device 10 will consider an over-temperature condition has been detected and will, in some embodiments, shut down the slave device 10 or a power device connected to the slave device 10. When the determined temperature is less than or equal to 150° C., the slave device 10 remains in the normal operation.

The slave device 10 is connected to the master device 12 via the single wire 16 to receive the digital signal S_{d} which may indicate a read or write command. The slave device 10 may respond to the read or write command by responding the digital signal S_{d} on the single wire 16. The digital signal S_{d} complies with a single wire protocol, including preamble data, header data, address data, DATA and acknowledge data and clock information.

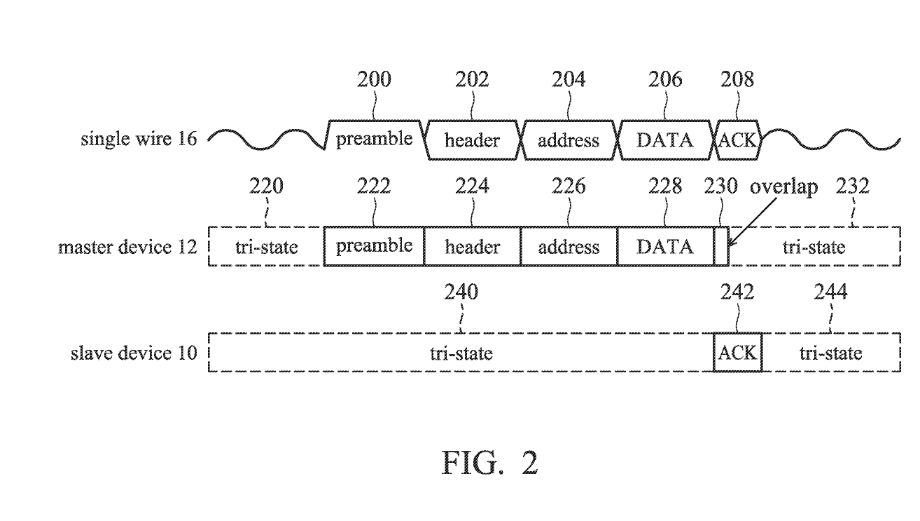

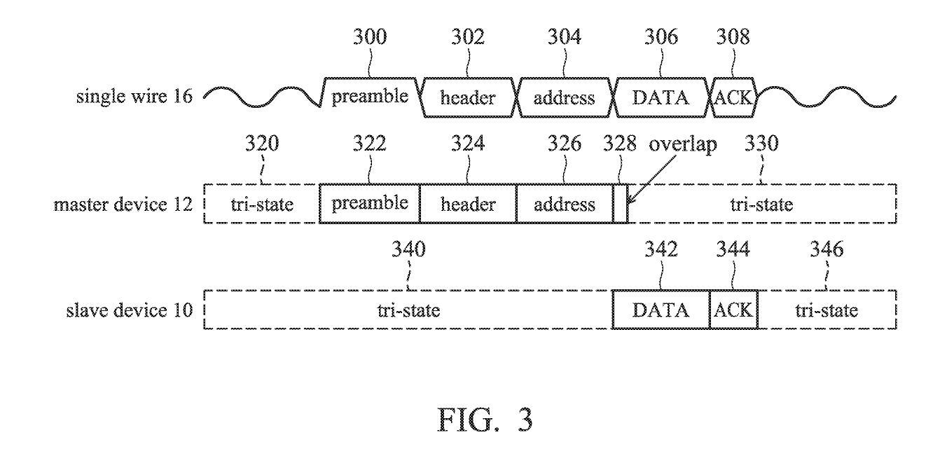

The read command may associate with reading a measurement, a configuration, or a parameter from the slave device 10. For example, the master device 12 may read a current measurement taken in the normal mode and adjust a configuration, a setting, or a parameter of the slave device 10 based on the read current measurement. FIG. 3 illustrates a read command being issued by the master device 12 to the slave device 10. The write command may associate with writing a configuration, a setting or a parameter into the slave device 10 to dynamically (write the data on-the-fly) or statically (write in a factory test) adjust the performance or behavior of the slave device 10. For example, the slave device 10 may be a switching mode power supply (SMPS) power controller IC, the master device 12 may write a configuration, a setting, or parameter into a temporary memory device of the power controller IC. The configuration, a setting, or parameter may vary the current limit and switching frequency of the output signal, or a reference voltage of the SMPS controller IC. FIG. 2 illustrates a write command being issued by the master device 12 to the slave device 10.

Following the preceding example, the slave device 10 may return to the normal mode after the configuration and parameter are adjusted, then operate with the new configuration, setting, or parameters and take the measurement accordingly. The master device 12 may initiate another command mode to determine whether the performance of the slave device 10 after the configuration adjustment complies with the desired or preferred performance, and re-configure the slave device 10 if the performance is unsatisfactory. After several iterations, a set of configuration, setting, and/or parameters, which complies with the desired and preferred performance, can be determined The master device 12 may write the set of the determined configuration, setting, and/or parameters into a laser fuse or a One-Time Programmable (OTP) ROM in the slave device 10, thereafter the slave device 10 can operate according to the set of the determined configuration, setting, and/or parameters written on the laser fuse or OTP ROM.

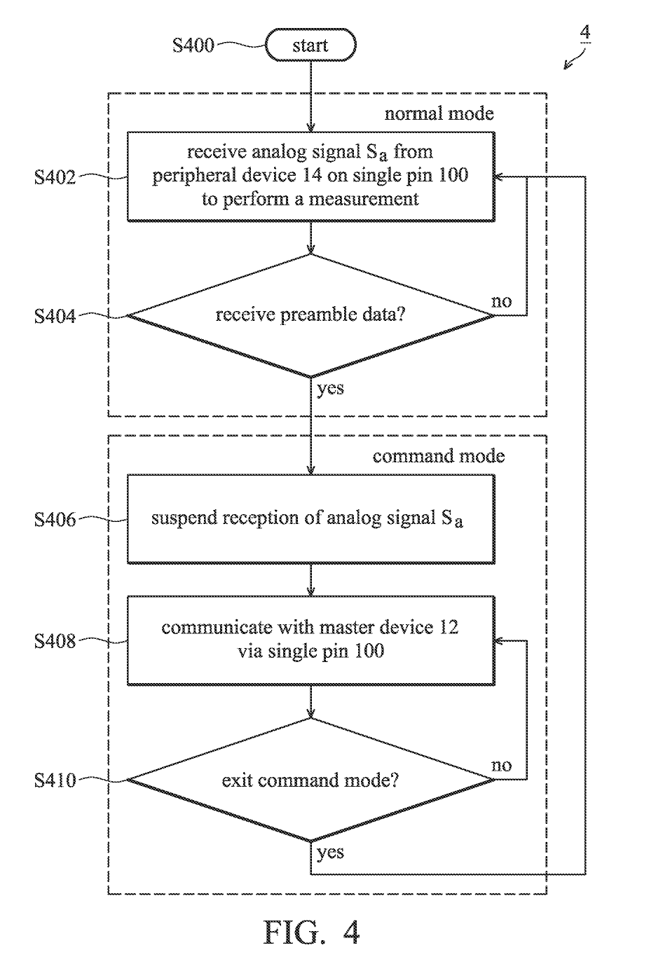

The slave device 10 includes a single pin 100 and a slave controller 102 coupled thereto. The master device 12 includes a single pin 120 and a master controller 122 coupled thereto. The master controller 122 initiates the command mode by issuing the preamble data on the single wire 16 via the single pin 120. Correspondingly, the slave device 10 can detect the preamble data while receiving the analog signal Sₐ via the single pin 100, and the slave controller 102 can determine that the master device 12 is going to issue a command upon recognizing the preamble data, and switch into the command mode, ready for acquiring the command from the master device 12. Having switched into the command mode, the slave device 10 can no longer detect the analog signal Sₐ or perform a measurement, instead, the salve device 10 can now communicate with the master device 12 on the single wire 16 using the single wire protocol outlined in FIGS. 3 and 4. In some embodiments, the slave controller 102 deactivates or disables all analog signal Sₐ associated circuits in the command mode.

The slave device 10 can exit the command mode when a timeout duration is expired or receive an exit command from the master device 12. The slave device 10 may be configured with a timeout duration which, when being exceeded without detecting any command on the single wire 16, the slave controller 102 will regard the timeout duration has been expired, and will exit the command mode and return the normal mode, resuming monitoring or receiving of the analog signal Sₐ from the peripheral device 14. In some implementations, the timeout duration may be set in the command mode. The master device 12 may also initiate termination of the command mode by transmitting an exit command on the single wire 16. In response to the exit command, the slave device 10 can switch back to the normal mode and in some embodiments, respond an acknowledge data on the single wire 16 to the master device 12, confirming that the command mode has been successfully exited. In some implementation, the slave device 10 automatically returns to the normal mode upon completion of an operation requested by the received command.

In some applications, the slave devices 10 are manufactured and provided in a default configuration and parameters to different clients, each client then adopt the multi- protocol communication system 1 to set the configuration and parameters according to a specific requirement or preference, providing flexibility for stock management, real-time programming, and configuration fine tuning on the fly.

Accordingly, the slave device 10 uses the single wire 16 to receive the analog signal Sₐ from the peripheral device 16 and communicates in the digital signal S_{d} with the master device 12, decreasing the pin count thereof and manufacturing cost, while providing flexibility of stock management, real-time programming, and fine tuning on the fly.

FIG. 2 shows a multi-protocol write procedure according to an embodiment of the invention, incorporating the multi-protocol communication system 1 in FIG. 1. FIG. 2 displays signals on the single wire 16, the pin 120 of the master device 12, and the pin 100 of the slave device 10.

Referring to the signals on the slave device 10, in the normal mode, the pin 100 of the slave device 10 is at a tri-state, capable of receiving the analog signal Sₐ from the peripheral device 14 and the digital signal S_{d} from the master device 12. Turning now to the master device 12, the master device 12 remains in a tri-state 220 when no command is transmitted. The master device 12 can initiate the programming of the slave device 10 by outputting preamble data 222, followed by header data 224, address data 226, and DATA 228 in the form of the digital signal S_{d} on the single wire 16. The preamble data 222 may be configured to pull up the voltage level at the pin 100 of the slave device 10 to a voltage VDD for longer than a predefined time duration (Tₛₜₐᵣₜ). The header data 222 may contain 12-bit consecutive logic 1, indicating the identifier of the data sender, i.e., the master device 12. The address data 224 and DATA 226 each may be 8-bit long. The address data 224 indicates the write operation and a destination or target address of the write operation. The DATA 226 is the data to be written into the destination or target address in the slave device 10.

Returning to the slave device 10, the slave device 10 remains at tri-state when the master device 12 transmits the command. In the normal mode, while the slave device 10 is receiving the analog signal Sₐ from the peripheral device 14, the preamble data can also be detected on the single wire 16. Upon detecting the preamble data, the slave device 10 recognizes that the master device 12 is going to request a command, thus switches from the normal mode to the command mode, suspending the reception of the analog signal Sₐ. The slave device 10 then receives the header data 224 and the address data 226 and the DATA 228. When the header data 224 matches with the identifier of the master device 12, the slave device 10 carries out the operation indicated by the address data 226 and the DATA 228. When the header data 224 does not match with the identifier of the master device 12, the slave device 10 aborts the command mode and returns to the normal mode. The slave device 10 is configured to record the configurations, settings or parameters into the internal register or NVM therein. After completing the operation indicated by the address data 226 and the DATA 228, the slave device 10 is configured to respond acknowledgement data 242 through the single wire 16 to the master device 12, indicating the write operation has been successfully completed. The slave device 10 then returns to a tri-state 244 for retrieving further command.

After sending the DATA 228 completely, the master device 12 pulls the voltage level of the pin 120 to the ground potential (the overlapped data segment 230) to wait for the acknowledgement data from the salve device 10. Concurrently, after receiving the DATA 228, the slave device 10 also pulls the pin 120 to “LOW” while responding the acknowledgement data 242 to the mater device 12 over the single wire 16. The acknowledgement data may contain 1-bit length ground potential then followed by 1-bit logic ‘1’ and then return to the tri-state. The procedure involving the data segments 222 through 230 and the data segment 242 is referred to as hand-shaking. Due to the considerably amount of noise coupling in the tri-state, both the master and slave devices are pulled low during the transmitting the acknowledgment data 242, to prevent from noise coupling and noise leakage.

The embodiment outlines the procedure for programming the slave device 10 by the master device 12 using the command mode, providing flexibility of stock management, real-time programming, and fine tuning on the fly.

FIG. 3 shows a multi-protocol read procedure according to an embodiment of the invention, incorporating the multi-protocol communication system 1 in FIG. 1, incorporating the multi-protocol communication system 1 in FIG. 1. FIG. 3 displays signals on the single wire 16, the pin 120 of the master device 12, and the pin 100 of the slave device 10.

The embodiment in FIG. 3 depicts the read procedure while the FIG. 2 illustrates the write procedure, the data 300 through 302, 320 through 324, and 340 in FIG. 3 are identical to the data 200 through 202, 220 through 224, and 240 in FIG. 2., reference therefor can be found in the preceding paragraphs and will not be repeated here.

Referring now to the master device 12, the address data 326 indicates the read operation and a target address addressing memory storage of the slave device 10 to be read from. The DATA 226 is the data to be written into the destination or target address in the slave device 10. After sending the address data 326 completely, the master device 12 pulls the pin 120 to the ground potential (overlapped data segment 328) while waiting for the DATA 342 from the slave device 10. Concurrently, in response to the received address data 326, the slave device 10 reads and outputs the content of the addressed internal register or NVM over the single wire 16 as DATA 344. Upon completing sending DATA 344, the slave device 10 further transmits acknowledgement data 344 over the single wire 16 to the master device 12, indicating the read operation has been completed. After sending the acknowledge data 344, the slave device 10 returns to a tri-state 346 for retrieving further command.

The embodiment outlines the procedure for downloading data from the slave device 10 by the master device 12 using the command mode, providing flexibility of stock management, real-time programming, and fine tuning on the fly.

FIG. 4 is a flowchart of a multi-protocol method 4 adopted by the slave device 10 according to an embodiment of the invention, incorporating the multi-protocol communication system 1 in FIG. 1

Upon startup, the slave device 10 enters the normal mode, and receives the analog signal Sₐ from the peripheral device 14 via the single pin 100 (S402). The analog signal Sₐ may be utilized by the slave device 10 to take current measurements, voltage measurement, temperature measurement, feed back output powers, supply auxiliary power, or provide other analog functions. Concurrently, the slave device 10 is configured to detect presence of the preamble data via the single pin 100 (S404). When the preamble data is absent from the pin 100, the slave device 10 remains in the normal mode and continues to obtain the analog signal Sₐ (S402).

When the preamble data is present on the pin 100, the slave device 10 switches from the normal mode to the command mode, suspends the reception of the analog signal Sa (S406), and communicates with the master device 12 in the serial digital data S_{d} via the single pin 100 (S408). The communication between the master device 12 and the slave device 10 is performed on the single wire 16, where the master device 12 may download the data from the slave device 10 (the read operation), or program the configuration and parameters into the slave device 10 (the write operation).

Upon completion of the operation requested by the master device 12, the slave device 10 then determines whether the condition for exiting the command mode is met (S410). When the condition for exit is not met, the slave device 10 returns to Step S408 to carry on the communication with the master device 12, waiting for further command. When the condition for exit is met, the slave device 10 switches from the command mode back to the normal mode, and resumes the measurement, power detection or power reception by receiving the analog signal Sₐ on the single wire 16 (S402). The condition for exiting the command mode may include expiration of the timeout duration, reception of the exit command from the master device 12, or completion of the present command operation. For example, the slave device 10 may be configured with a timeout duration of 3 seconds, when no command is received on the single wire 16 for longer than 3 seconds, the slave controller 102 will regard the timeout duration has been expired, and will exit the command mode and return the normal mode, resuming receiving of the analog signal Sₐ from the peripheral device 14. In another example, the slave device 10 may receive an exit command on the single wire 16. In response to the exit command, the slave device 10 can switch back to the normal mode and in some embodiments, respond an acknowledge data on the single wire 16 to the master device 12, confirming that the command mode has been successfully exited. In yet another example, the slave device 10 automatically returns to the normal mode upon completion of an operation requested by the received command.

The multi-protocol method 4 allows the slave device 10 to detect the analog signal Sₐ from the peripheral device 16 and communicate with the master device 12 in the digital signal S_{d} on the single wire 16, decreasing the pin count thereof and manufacturing cost, while providing flexibility of stock management, real-time programming, and fine tuning on the fly.

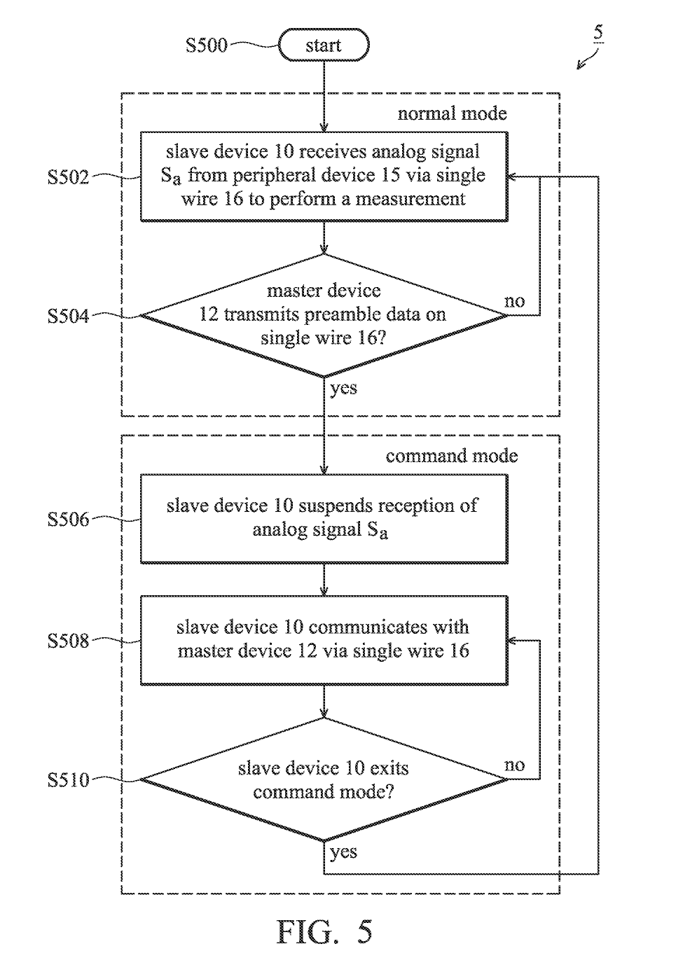

FIG. 5 is a flowchart of a multi-protocol method 5 adopted by the multi- protocol communication system 1 in FIG. 1 according to an embodiment of the invention. The multi-protocol method 5 may be adopted in the factory testing for power controller ICs, with the slave device 10 being the power controller IC under test.

Upon startup, the slave device 10 is in the normal mode, receiving the analog signal Sₐ from the peripheral device 14 via the single pin 100 (S502) while determining presence of the digital signal S_{d} on the single wire 16 via the single pin 100. The analog signal Sₐ may be utilized by the slave device 10 to take current measurements, voltage measurement, temperature measurement, feed back output powers, supply auxiliary power, or provide other analog functions. When the preamble data, or the digital signal S_{d}, is absent from the pin 100, the slave device 10 remains in the normal mode and continues to obtain the analog signal Sₐ (S502).

When requesting a command to the slave device 10, the master device 12 is configured to transmit preamble data on the single wire (S504). Correspondingly, the slave device will detect the preamble data via the pin 100, switch from the normal mode to the command mode, suspend the reception of the analog signal Sₐ (S506), and communicate with the master device 12 via the single wire 16 (S508). The communication between the master device 12 and the slave device 10 is performed on the single wire 16, where the master device 12 may download the data from the slave device 10 (the read operation), or program the configuration and parameters into the slave device 10 (the write operation).

Upon completion of the operation requested by the master device 12, the slave device 10 then determines whether the condition for exiting the command mode is met (S410). When the condition for exit is not met, the slave device 10 returns to Step S508 to carry on the communication with the master device 12, waiting for another command. When the condition for exit is met, the slave device 10 switches from the command mode back to the normal mode, and resumes the measurement, power detection or power reception by receiving the analog signal Sₐ on the single wire 16 (S502). The condition for exiting the command mode may include expiration of the timeout duration, reception of the exit command from the master device 12, or completion of the present command operation. Details therefor can be found in the preceding paragraphs for FIG. 4.

The multi-protocol method 5 allows the multi-protocol communication system 1 to operate with the analog signal Sₐ and the digital signal S_{d} on the single wire 16, decreasing the pin count thereof and manufacturing cost, while providing flexibility of stock management, real-time programming, and fine tuning on the fly.

As used herein, the term “determining” encompasses calculating, computing, processing, deriving, investigating, looking up (e.g., looking up in a table, a database or another data structure), ascertaining and the like. Also, “determining” may include resolving, selecting, choosing, establishing and the like.

The various illustrative logical blocks, modules and circuits described in connection with the present disclosure may be implemented or performed with a general- purpose processor, a digital signal processor (DSP), an application-specific integrated circuit (ASIC), a field programmable gate array signal (FPGA) or other programmable logic device, discrete gate or transistor logic, discrete hardware components or any combination thereof designed to perform the functions described herein. A general purpose processor may be a microprocessor, but in the alternative, the processor may be any commercially available processor, controller, microcontroller or state machine.

The operations and functions of the various logical blocks, units, modules, circuits and systems described herein may be implemented by way of, but not limited to, hardware, firmware, software, software in execution, and combinations thereof

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An integrated circuit, coupled to a digital circuitry and an analog circuitry, wherein the integrated circuit is capable of operating in first and second operation modes, the integrated circuit comprising:
a single pin, in the first operation mode, configured to receive an analog signal from the analog circuitry and receive a digital signal containing a preamble pattern from the digital circuitry; and
a controller, coupled to the single pin, after detecting the preamble pattern, configured to switch from the first to the second operation mode to suspend receiving the analog signal via the single pin and communicating with the digital circuitry in serial digital data via the single pin.

2. The integrated circuit of claim 1, wherein when no command data is received from the digital circuitry in a timeout period, the controller is configured to switching from the second to the first operation mode.

3. The integrated circuit of claim 1, wherein the single pin is configured to receive command data from the digital circuitry, indicating a mode switch to the first operation mode; and
in response to the received command data, the controller is configured to switch from the second to the first operation mode.

4. The integrated circuit of claim 1, wherein upon completion of an operation initiated by the digital circuitry, the controller is configured to switch from the second to the first operation mode.

5. The integrated circuit of claim 1, wherein the controller is further configured to:
receive header data which identifies the digital circuitry from the digital circuitry;
receive command data from the digital circuitry, which indicates an operation for the integrated circuit to perform;
perform the operation based on the command data; and
after completion of the operation, transmit acknowledgement data to the digital circuitry.

6. The integrated circuit of claim 5, wherein the operation include writing a parameter into the integrated circuit.

7. The integrated circuit of claim 5, wherein the operation include reading a parameter from the integrated circuit to the digital circuitry.

8. The integrated circuit of claim 1, wherein integrated circuit is a power converter circuit; and
the analog circuitry includes an optic coupler, a capacitive isolator and an inductive isolator, isolating between a primary and a secondary sides of the power converter circuit.

9. The integrated circuit of claim 1, wherein the controller is further configured to determine a current based on the analog signal in the first operation mode.

10. The integrated circuit of claim 1, wherein the controller is further configured to determine a voltage based on the analog signal in the first operation mode.

11. The integrated circuit of claim 1, wherein the controller is further configured to determine a temperature based on the analog signal in the first operation mode.

12. A method, adopted by an integrated circuit coupled to a digital circuitry and an analog circuitry, wherein the integrated circuit is capable of operating in first and second operation modes, the method comprising:
in the first operation mode, receiving an analog signal from the analog circuitry by a single pin of the integrated circuit;
receiving a digital signal containing a preamble pattern from the digital circuitry by the single pin; and
after detecting the preamble pattern, switching from the first to the second operation mode which comprises steps of suspending receiving the analog signal by the single pin, and communicating with the digital circuitry in serial digital data via the single pin.

13. The method of claim 12, further comprising:
when no command data is received from the digital circuitry in a timeout period during the communicating step, switching from the second to the first operation mode.

14. The method of claim 12, further comprising:
receiving command data from the digital circuitry, indicating a mode switch to the first operation mode; and
in response to the received command data, switching from the second to the first operation mode.

15. The method of claim 12, further comprising:
upon completion of an operation initiated by the digital circuitry during the communicating, switching from the second to the first operation mode.

16. The method of claim 12, wherein communicating step comprises:
receiving header data which identifies the digital circuitry from the digital circuitry;
receiving command data from the digital circuitry, which indicates an operation for the integrated circuit to perform;
performing the operation based on the command data; and
after completion of the operation, transmitting acknowledgement data to the digital circuitry.

17. The method of claim 12, further comprising determining a voltage, current, or temperature characteristic based on the analog signal in the first operation mode.

18. A method, adopted by a multi-protocol system containing a master device, an analog circuitry and a slave device coupled together by a single wire, wherein the slave device is capable of operating in first and second operation modes, the method comprising:
receiving, by the slave device in the first operation mode, an analog signal from the peripheral device on a single wire;
transmitting, by the master device, a digital signal containing a preamble pattern on the single wire; and
after detecting the preamble pattern, switching, by the slave device, from the first to the second operation mode which comprises suspending receiving the analog signal on the single wire, and communicating with the master device in serial digital data via the single wire.

19. The method of claim 18, further comprising:
when no command data is received from the master device in a timeout period during the communicating step, switching, by the slave device, from the second to the first operation mode.

20. The method of claim 18, further comprising:
receiving, by the slave device, command data from the master device, indicating a mode switch to the first operation mode; and
in response to the received command data, switching from the second to the first operation mode by the slave device.

21. The method of claim 18, further comprising:
upon completion of an operation initiated by the master device during the communicating, switching from the second to the first operation mode by the slave device.
